(19) United States
(12) Patent Application Publication
(10) Pub. No.: US 2015/0189755 A1
(43) Pub. Date: Jul. 2, 2015

(54) DISPLAY MODULE AND DISPLAY APPARATUS HAVING THE SAME

(71) Applicant: SAMSUNG ELECTRONICS CO., LTD., Suwon-si (KR)

(72) Inventor: Woo Sub CHOI, Incheon (KR)

(73) Assignee: SAMSUNG ELECTRONICS CO., LTD., Suwon-si (KR)

(21) Appl. No.: 14/588,750

(22) Filed: Jan. 2, 2015

(30) Foreign Application Priority Data
Jan. 2, 2014 (KR) 10-2014-0000465

(51) Int. Cl. H05K 1/14; H05K 1/02; H05K 1/18

(52) U.S. Cl. CPC H05K 1/147; H05K 1/18; H05K 1/028; H05K 2201/10128; H05K 2201/09063

(57) ABSTRACT

Disclosed herein is a flexible printed circuit board configured to extend from a display panel to a source printed circuit board, and connect the display panel and the source printed circuit board. The flexible printed circuit board is provided with a slit extending longitudinally in an extension direction thereof, to reduce damage to the flexible printed circuit board that may occur by a force acting on the flexible printed circuit board when the display panel is bent.

### CROSS-REFERENCE TO RELATED APPLICATION

This application claims priority from Korean Patent Application No. 2014-0000465, filed on Jan. 2, 2014 in the Korean Intellectual Property Office, the disclosure of which is incorporated herein by reference in its entirety.

### BACKGROUND

1. Field

Methods and apparatuses consistent with exemplary embodiments relate to a display module including a display panel having both side ends protrude in a forward direction and a display apparatus having the same.

2. Description of Related Art

In general, a display apparatus includes a display panel on which an image is displayed.

The display apparatus includes a display panel for displaying an image, a source printed circuit board for controlling the display panel, a backlight unit for emitting light into the display panel, etc.

The source printed circuit board for controlling the display panel is spaced apart from a rear side of the display panel, and the display panel and the source printed circuit board are connected to each other through flexible printed circuit boards.

Among such display apparatuses, a display apparatus has been recently presented in which both side ends of the display panel are bent to protrude in a forward direction, so that a stereoscopic effect similar to a three-dimensional image may be experienced, even through a two-dimensional image.

### SUMMARY

In accordance with an aspect of an exemplary embodiment, a display apparatus includes a display module configured to display an image, wherein the display module includes: a display panel including a plurality of side ends bent to protrude in a forward direction; a source printed circuit board configured to control the display panel; and a flexible printed circuit board extending in a first direction from the display panel to the source printed circuit board and connecting the display panel to the source printed circuit board, wherein the flexible printed circuit board includes at least one slit provided to run in an extension direction thereof.

The at least one slit may include a plurality of slits formed to be spaced apart and in parallel with each other.

The source printed circuit board may be disposed on a rear side of the display panel; the flexible printed circuit board may include a curved portion bent in a U-shape; and the at least one slit may be formed in the curved portion.

The flexible printed circuit board may include circuits formed therein; and the circuits may be formed in a limited area excluding both sides of the extension direction of the slit.

The flexible printed circuit board may include a panel connecting portion that extends from the curved portion and is connected to the display panel; and the panel connecting portion may be bent to correspond to the display panel.

The flexible printed circuit board may include a board connecting portion that extends from the curved portion and is connected to the source printed circuit board; and the flexible printed circuit board may include a chip disposed on the board connecting portion.

In accordance with another exemplary aspect, a display module includes: a display panel whose both side ends are bent to protrude in a forward direction; a source printed circuit board configured to control the display panel; and a flexible printed circuit board extending in a first direction from the display panel to the source printed circuit board and connecting the display panel to the source printed circuit board. The flexible printed circuit board includes at least one slit provided the first direction.

The at least one slit may include a plurality of slits spaced apart and in parallel with each other.

The source printed circuit board may be disposed on a rear side of the display panel; the flexible printed circuit board may include a curved portion bent in a U-shape; and the at least one slit may be formed in the curved portion.

The flexible printed circuit board may include circuits formed therein; and the circuits may be formed in a limited area excluding both sides of the extension direction of the slit.

The flexible printed circuit board may include a panel connecting portion that extends from the curved portion and is connected to the display panel; and the panel connecting portion may be bent to correspond to the display panel.

The flexible printed circuit board may include a board connecting portion that extends from the curved portion and is connected to the source printed circuit board; and the flexible printed circuit board may include a chip disposed on the board connecting portion.

In accordance with yet another aspect of an exemplary embodiment a flexible printed circuit board configured to connect a display panel and a source printed circuit board, the flexible printed circuit board may include: a first portion configured to connect to the display panel; a second portion configured to connect to the source printed circuit board; and a curved portion connecting the first portion and the second portion and including at least one slit.

The at least one slit may include a plurality of slits spaced apart and in parallel with each other.

The flexible printed circuit board may include a curved portion bent in a U-shape; and the at least one slit may be formed in the curved portion.

The display module may include circuits formed therein; and the circuits may be formed in a limited area excluding both sides of the extension direction of the at least one slit.

The flexible printed circuit board may include a chip disposed on the second portion.

The first portion may include at least one slit.

The second portion may include at least one slit.

The display panel may include a plurality of sides bent to protrude in a forward direction.

### BRIEF DESCRIPTION OF THE DRAWINGS

These and/or other aspects will become apparent and more readily appreciated from the following description of the exemplary embodiments, taken in conjunction with the accompanying drawings in which:

FIG. 1 is a perspective view of a display apparatus in accordance with an exemplary embodiment;

FIG. 2 is a perspective view of a display panel in accordance with another exemplary embodiment;

FIG. 3 is an enlarged view of portion A of FIG. 2; and

FIG. 4 is a deployment view of a flexible printed circuit board in accordance with still another exemplary embodiment.

### DETAILED DESCRIPTION OF EXEMPLARY EMBODIMENTS

Hereinafter, exemplary embodiments will be described in detail with reference to the accompanying drawings. However, one or more exemplary embodiments may be embodied in many different forms, and should not be construed as being limited to exemplary embodiments set forth herein. Rather, these exemplary embodiments are provided so that this disclosure will be thorough and complete, and will fully convey the concept of the one or more exemplary embodiments to those of ordinary skill in the art. In the following description, unrelated parts may be omitted for clarity. Like reference numbers refer to like or similar elements throughout. Expressions such as “at least one of,” when preceding a list of elements, modify the entire list of elements and do not modify the individual elements of the list.

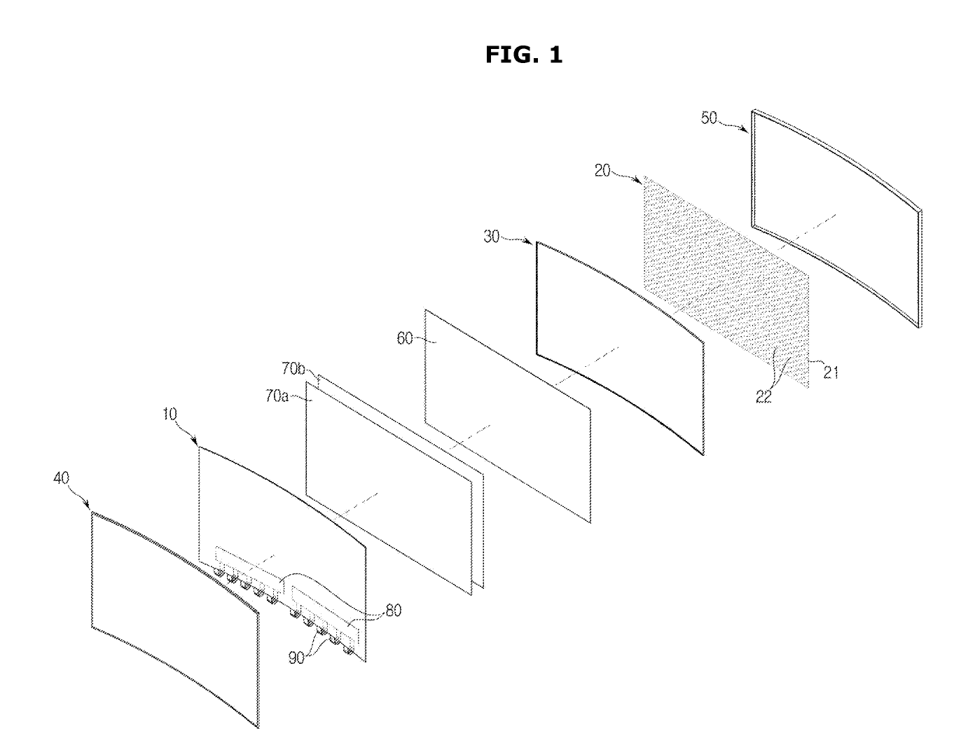

FIG. 1 is a perspective view of a display apparatus including a display module in accordance with an exemplary embodiment.

As shown in FIG. 1, the display module includes a display panel 10 on which an image is displayed, a backlight unit 20 that is disposed on a rear side of the display panel 10 and emits light into the display panel 10, a middle mold 30 which supports the display panel 10, a top sash 40 that maintains a state in which the display panel 10 is installed on the middle mold 30, and a bottom sash 50 that accommodates the backlight unit 20 on an inner side thereof and is coupled to a rear side of the middle mold 30. In addition, a diffusion plate 60 capable of diffusing light emitted from the backlight unit 20, and optical sheets 70a and 70b capable of improving the optical property of light incident on the diffusion plate 60 are disposed between the display panel 10 and the backlight unit 20.

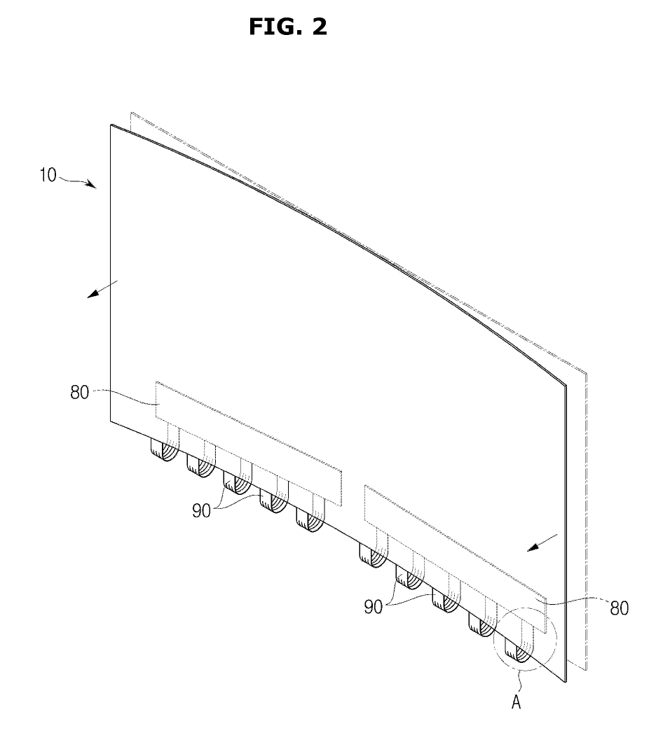

The display panel 10 may be formed with a liquid crystal display panel. As shown in FIG. 2, source printed circuit boards 80 for controlling the display panel 10 are connected to a lower end of the display panel 10 through flexible printed circuit boards 90. In the exemplary embodiment, the source printed circuit boards 80 are connected to the display panel 10 by a plurality of flexible printed circuit boards 90.

The flexible printed circuit boards 90 extend from the lower end of the display panel 10 toward the source printed circuit boards 80, are spaced apart from a lower rear side of the display panel 10 and connect the display panel 10 to the source printed circuit boards 80. Circuits for transmitting a signal and a power source may be included in the flexible printed circuit boards 90.

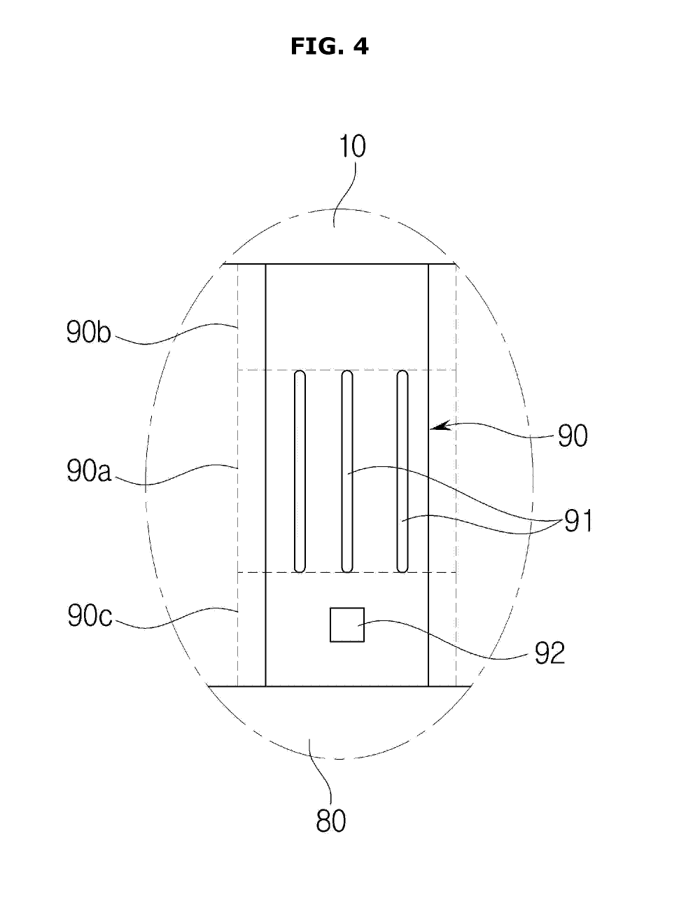

The center portions of the flexible printed circuit boards 90 are bent to be substantially curved in a U-shape so that the display panel 10 and the source printed circuit boards 80 are connected. As shown in FIG. 4, the flexible printed circuit board 90 is provided with a curved portion 90a that is bent to be curved in a center thereof, provided with a panel connecting portion 90b that is connected to the display panel 10, and provided with a board connecting portion 90c that is connected to the source printed circuit board 80 and in back of the curved portion 90a. In the exemplary embodiment, a chip 92 is mounted on the board connecting portion 90c.

Referring back to FIG. 1, the optical sheets 70a and 70b include a prism sheet 70b that has a prism-like pattern and concentrates light diffused by the diffusion plate 60 in a direction perpendicular to the display panel 10, and a protection sheet 70a that is disposed on a front side of the prism sheet 70b and protects the prism sheet 70b.

The top sash 40 is formed in a rectangular ring shape, is coupled to a front side of the middle mold 30, supports edges of a front surface of the display panel 10, and maintains a state in which the display panel 10 is installed on the middle mold 30.

The middle mold 30 is seated on and supported by the display panel 10, and is coupled to the bottom sash 50.

The bottom sash 50 is formed by a metal plate, such as aluminum, and the backlight unit 20 is installed inside the bottom sash 50 so that heat generated from the backlight unit 20 may be dissipated through the bottom sash 50.

The backlight unit 20 includes a printed circuit board 21 that is formed in a flat shape, and a plurality of light emitting diodes 22 that are mounted on the printed circuit board 21.

As described above, the top sash 40, the bottom sash 50 and the middle mold 30 may be produced so that the both side ends thereof are bent so as to protrude in a forward direction, the display panel 10, the diffusion plate 60, the optical sheets 70a and 70b, and the backlight unit 20 may be bent and curved to correspond to a shape which supports the top sash 40, and the bottom sash 50 and the middle mold 30 may be formed to be curved.

As described above, when the display panel 10 is bent, the panel connecting portion 90b connected to the display panel 10 may be bent to be curved similar to the display panel 10, but since the curved portion 90a is bent in a U-shape, the curved portion 90a may not be bent so that both sides protrude in a forward direction so as to correspond to the display panel 10.

Due to the curvature, a force acts on the both sides of the curved portion 90a in a forward direction. When this state is maintained over a long period of time, the curved portion 90a may develop a lateral fold as a result of the force acting on the both sides. Accordingly, circuits formed in the curved portion 90a may be damaged.

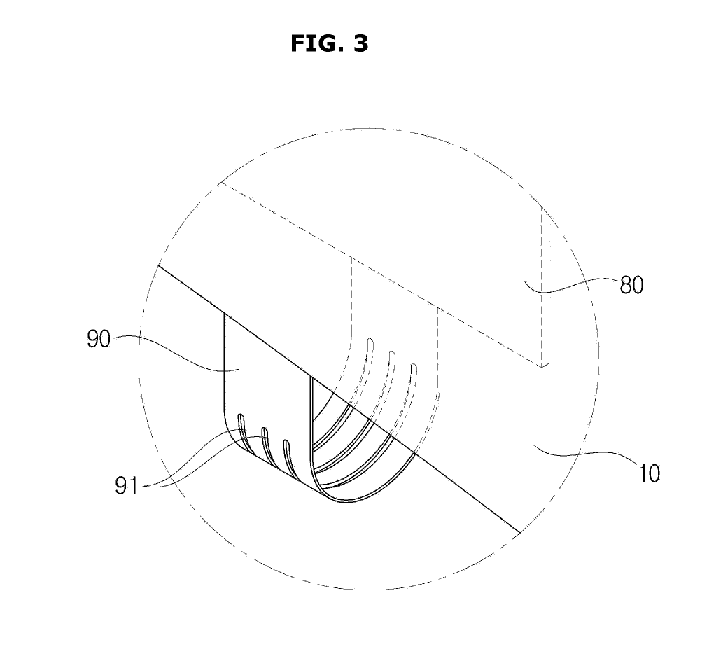

Thus, as shown in FIGS. 3 and 4, a plurality of slits 91 that are elongated in an extension direction of the flexible printed circuit board 90, and spaced apart in parallel, are provided in the curved portion 90a. Also, the circuits described above may be formed in a limited area on the flexible printed circuit board 90, excluding an area immediately surrounding the longitudinal ends of the plurality of slits 91.

As described above, when the slits 91 are formed in the curved portion 90a and the curved portion 90a is partially bent, the slits 91, may reduce the force acting on the curved portion 90a.

Further, when the curved portion 90a is folded laterally, the folded phenomenon may still appear. As described above, since the circuits may be formed only in the area excluding the area immediately surrounding the longitudinal ends of the slits 91, even when the curved portion 90a is folded laterally based on the slits 91, the circuits are not damaged.

According to an aspect of an exemplary embodiment, the display apparatus may be configured to include a case that accommodates the display module, various printed circuit boards for controlling the display module, and a stand that may support the display apparatus.

According to an aspect of an exemplary embodiment, the flexible printed circuit board 90 may be provided with any number of slits, including only one slit 91.

According to an aspect of an exemplary embodiment, the slits 91 may also be formed on all or part of the panel connecting portion 90b and the board connecting portion 90c.

As described above, because the flexible printed circuit board 90 is provided with one or more slits 91 in an extension direction thereof, even when a force acts on the flexible printed circuit board 90 during a process of bending the display panel, damage to the flexible printed circuit board 90 due to the force can be avoided.

Also, because the circuits are formed in a limited area of the flexible printed circuit board 90 excluding both sides of the extension direction of the slit 91, even when the flexible printed circuit board is folded around the slit, the circuits are not damaged.

One or more exemplary embodiments are not limited to the exemplary embodiments described above, and various modifications and changes that do not depart from the spirit and scope of the invention will be possible by those skilled in the art. Accordingly, all such modifications and changes are also deemed to be covered by the claims of the invention.

What is claimed is:

1. A display apparatus comprising:
a display module configured to display an image, the display module comprising:
a display panel comprising a plurality of side ends bent to protrude in a forward direction;
a source printed circuit board configured to control the display panel; and
a flexible printed circuit board extending in a first direction from the display panel to the source printed circuit board and connecting the display panel to the source printed circuit board,
wherein the flexible printed circuit board comprises at least one slit provided in the first direction.

2. The display apparatus of claim 1, wherein the at least one slit comprises a plurality of slits spaced apart and in parallel with each other.

3. The display apparatus of claim 1, wherein:
the source printed circuit board is disposed on a rear side of the display panel;
the flexible printed circuit board comprises a curved portion bent in a U-shape; and
the at least one slit is formed in the curved portion.

4. The display apparatus of claim 1, wherein:
the flexible printed circuit board comprises circuits formed therein; and
the circuits are formed in a limited area excluding both sides of the extension direction of the slit.

5. The display apparatus of claim 3, wherein:
the flexible printed circuit board comprises a panel connecting portion that extends from the curved portion and is connected to the display panel; and
the panel connecting portion is bent to correspond to the display panel.

6. The display apparatus of claim 3, wherein:
the flexible printed circuit board comprises a board connecting portion that extends from the curved portion and is connected to the source printed circuit board; and
the flexible printed circuit board comprises a chip disposed on the board connecting portion.

7. A display module, comprising:
a display panel whose both side ends are bent to protrude in a forward direction;
a source printed circuit board configured to control the display panel; and
a flexible printed circuit board extending in a first direction from the display panel to the source printed circuit board and connecting the display panel to the source printed circuit board,
wherein the flexible printed circuit board comprises at least one slit provided in the first direction.

8. The display module of claim 7, wherein:
the at least one slit comprises a plurality of slits spaced apart and in parallel with each other.

9. The display module of claim 7, wherein:
the source printed circuit board is disposed on a rear side of the display panel;
the flexible printed circuit board comprises a curved portion bent in a U-shape; and
the at least one slit is formed in the curved portion.

10. The display module of claim 7, wherein:
the flexible printed circuit board comprises circuits formed therein; and
the circuits are formed in a limited area excluding both sides of the extension direction of the slit.

11. The display module of claim 9, wherein:
the flexible printed circuit board comprises a panel connecting portion that extends from the curved portion and is connected to the display panel; and
the panel connecting portion is bent to correspond to the display panel.

12. The display module of claim 9, wherein:
the flexible printed circuit board comprises a board connecting portion that extends from the curved portion and is connected to the source printed circuit board; and
the flexible printed circuit board comprises a chip disposed on the board connecting portion.

13. A flexible printed circuit board configured to connect a display panel and a source printed circuit board, the flexible printed circuit board comprising:
a first portion configured to connect to the display panel;
a second portion configured to connect to the source printed circuit board; and
a curved portion connecting the first portion and the second portion and comprising at least one slit.

14. The flexible printed circuit board of claim 13, wherein the at least one slit comprises a plurality of slits spaced apart and in parallel with each other.

15. The flexible printed circuit board of claim 13, further comprising:
a curved portion bent in a U-shape; and
the at least one slit is formed in the curved portion.

16. The display module of claim 13, further comprising circuits formed therein,
wherein the circuits are formed in a limited area excluding both sides of the extension direction of the at least one slit.

17. The flexible printed circuit board of claim 15, further comprising a chip disposed on the second portion.

18. The flexible printed circuit board of claim 13, wherein the first portion comprises at least one slit.

19. The flexible printed circuit board of claim 18, wherein the second portion comprises at least one slit.

20. The flexible printed circuit board of claim 13, wherein the display panel comprises a plurality of side ends bent to protrude in a forward direction.
